(19) United States
(12) Patent Application Publication
(10) Pub. No.: US 2004/0094782 A1
(43) Pub. Date: May 20, 2004

(54) Use of hafnium silicon oxynitride as the cap layer of the sidewall spacer

(76) Inventors: Yuanning Chen, Plano, TX (US); Mark R. Visokay, Richardson, TX (US)

Correspondence Address: TEXAS INSTRUMENTS INCORPORATED, P O BOX 655474, M/S 3999, DALLAS, TX, 75265

(21) Appl. No.: 10/294,265

(22) Filed: Nov. 14, 2002

(51) Int. Cl. H01L 29/76; H01L 31/062; H01L 21/336

(52) U.S. Cl. 257/288; 257/336; 438/303

(57) ABSTRACT

An embodiment of the invention is a CMOS transistor where the cap layer 9 of the sidewall spacer structure 7, 8, 9, 10, and 11 is comprised of a high dielectric constant material.

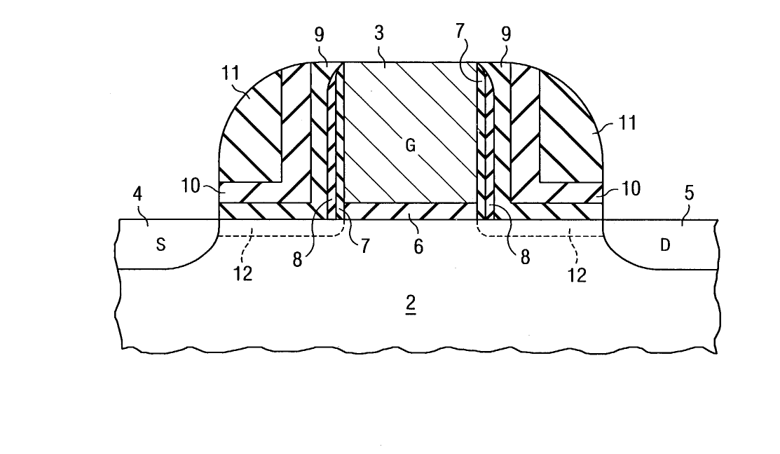

### BACKGROUND OF THE INVENTION

This invention relates to the use of a high dielectric constant material as the cap layer of a MOS transistor.

### BRIEF DESCRIPTION OF THE DRAWINGS

The drawing shows a MOS transistor having a cap layer comprised of a high dielectric material in accordance with the invention.

### DETAILED DESCRIPTION OF THE INVENTION

In the conventional sidewall spacer used with sub-100 nm CMOS technology, the dopant loss of the Lightly Doped Drain junction adversely affects the transistor's drive current. The use of a high dielectric constant material as the cap layer of the sidewall spacer improves the transistor's drive current. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention.

Referring to the drawing, the best mode application of the invention is a p-channel MOS (“PMOS”) transistor formed within a n-well region 2. The PMOS transistor is created by gate 3, source 4, and drain 5. In this example, the source 4 and drain 5 have p-type dopants. In addition, the PMOS gate is created from p-type doped polysilicon 3 and gate oxide 6.

A sidewall spacer is used to improve the hot carrier-aging problem related to transistor reliability. An oxide layer 7, an offset nitride layer 8, a cap layer 9, a silicon nitride layer 10, and another oxide layer 11 create the sidewall spacer.

In applications where the cap layer 9 is comprised of oxide, the lateral diffusion of the source/drain impurities during the fabrication of the PMOS transistor cause the boron dopants in the Lightly Doped Drain (“LDD”) junction 12 to move into the cap layer 9. This migration of dopants from the LDD junction 12 to the cap layer 9 will lower the doping level in the LDD junction, thereby raising the external resistance of the transistor. As a result, the drive current will be reduced and the performance of the transistor will be adversely affected.

In the best mode application the cap layer 9 is made of a high dielectric constant (“high-k”) material such as hafnium silicon oxynitride (“HfSiON”), which has a dielectric constant of approximately 12. When the transistor is turned on, the high-k cap layer 9 will create an accumulation layer in the LDD junction 12 (at the interface with the cap layer 9) that will decrease the external resistance in that area. The nitrogen content in HfSiON will also serve to block the migration of dopants out of the LDD junction 12. As a result, the external resistance is reduced, the drive current is increased, and the operating speed of the transistor is increased. Thus the use of a high-k cap layer 9 improves the transistor performance and a nitrogen-containing high-k material such as HfSiON improves the transistor performance even further.

Various modifications to the invention as described above are within the scope of the claimed invention. As an example, instead of implementing this invention in an PMOS transistor, it may also be implemented in a n-channel MOS (“NMOS”) transistor. In addition, a different high-k material may be used to create the cap layer 9 (i.e. HfON, HfO₂, ZeSiON, ZrSiO, ZrO, ZiON, Al₂O₃, HfAlO, and ZrAlO). Furthermore, it is within the scope of this invention to create the transistor having a Medium Doped Drain (“MDD”) or Highly Doped Drain (“HDD”) junction instead of the LDD junction 12. Moreover, this invention may be implemented in a sidewall spacer structure that is comprised of different materials or layers than is described above.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A circuit comprising:
a MOS transistor having a cap layer comprised of a high dielectric constant material.

2. The circuit of claim 1 wherein said high dielectric constant material is hafnium silicon oxynitride.

3. The circuit of claim 1 wherein said MOS transistor is a PMOS transistor.

4. The circuit of claim 1 wherein said MOS transistor is a NMOS transistor.

5. A MOS transistor comprising:
a cap layer comprised of a high dielectric constant material.

6. The MOS transistor of claim 5 wherein said high dielectric constant material is hafnium silicon oxynitride.

7. The MOS transistor of claim 5 wherein said MOS transistor is a NMOS transistor.

8. The MOS transistor of claim 5 wherein said MOS transistor is a PMOS transistor.

9. A PMOS transistor comprising:
a cap layer comprised of a high dielectric constant material.

10. The PMOS transistor of claim 9 wherein said high dielectric constant material is hafnium silicon oxynitride.

11. A PMOS transistor comprising:
a cap layer comprised of hafnium silicon oxynitride.
